(19) United States
(12) Patent Application Publication
(10) Pub. No.: US 2024/0162124 A1
(43) Pub. Date: May 16, 2024

(54) OPTOCOUPLER, LEAD FRAME AND MANUFACTURING METHOD THEREFOR

(71) Applicant: FOSHAN NATIONSTAR OPTOELECTRONICS CO., LTD., Foshan (CN)

(72) Inventors: Mingjun ZHU, Foshan (CN); Yurong LI, Foshan (CN); Haojie GUO, Foshan (CN); Xiaopeng YU, Foshan (CN); Huijuan LIU, Foshan (CN); Yinling ZHENG, Foshan (CN)

(73) Assignee: FOSHAN NATIONSTAR OPTOELECTRONICS CO., LTD., Foshan, GD (CN)

(21) Appl. No.: 18/509,924

(22) Filed: Nov. 15, 2023

(30) Foreign Application Priority Data
Nov. 16, 2022 (CN) 202211434404.2

(51) Int. Cl. H01L 23/495; H01L 33/34; H01L 33/56; H01L 33/62

(52) U.S. Cl. CPC H01L 23/49575; H01L 23/49513; H01L 33/34; H01L 33/56; H01L 33/62

(57) ABSTRACT

A lead frame for an optocoupler is provided, which is a metal sheet and includes multiple frame units and multiple mutually parallel connecting strips. The frame units are arranged at intervals on each of the connecting strips. Each of the frame units includes two adjacent functional parts, and two pins perpendicularly connected to the connecting strip. The two functional parts are both located on one side of the connecting strip and are respectively connected to the two pins and ends of the two pins are located on the other side of the connecting strip. The area of each of the functional parts is sufficient to accommodate a chip to be installed and fixed, and the chip is any one of a light-emitting chip and a light-sensing chip.

### CROSS-REFERENCE TO RELATED APPLICATIONS

This disclosure claims priority to Chinese Patent Application No. 202211434404.2 filed Nov. 16, 2022, the disclosure of which is incorporated herein by reference in its entirety.

### TECHNICAL FIELD

The present disclosure relates to the technical field of optocouplers, and in particular to an optocoupler, a lead frame and a manufacturing method for the optocoupler.

### BACKGROUND

As a safety device for electric-optic-electric conversion and isolation, an optocoupler has a wide range of applications. Generally, an optocoupler mainly includes a light-emitting chip and a light-sensing chip. The light-emitting chip and the light-sensing chip are encapsulated in the same encapsulation body with encapsulating glue. When an electrical signal is applied to an input terminal of the optocoupler, the light-emitting chip, such as an infrared light-emitting diode, will emit infrared light, and the light-sensing chip at a receiving terminal will generate an induced current after receiving the infrared light, thus achieving the conversion between an optical signal and an electrical signal.

The current transfer ratio (CTR) is the main characteristic index of the optocoupler, and the induced current of the optocoupler when operating is directly related to factors such as the energy of light emitted by the diode, the opposed position design and the spacing distance design of the light-emitting chip and the light-sensing chip within the encapsulation body, and the transmittance of materials between the light-emitting chip and the light-sensing chip.

The common internal encapsulation structures of the conventional optocouplers include a vertically opposed type, an obliquely opposed type, a horizontal reflective type and other types, in which the opposed type is the solution with the least light waste. However, the deviation between the opposed positions of the two types of chips under this solution will directly cause the surface of the photosensitive semiconductor tube to receive less infrared light, adversely affecting the induced current generated and ultimately affecting the consistency of the CTR. In conventional opposed-type optocouplers, since the light-emitting chip and the light-sensing chip respectively use lead frames with different structures, the opposed positions are more likely to be deviated from each other. Moreover, it is necessary to develop molds separately for manufacturing respective lead frames for the two types of chips, which significantly increases the manufacturing costs. In addition, in the process of placing and bonding the two types of chips, different machines need to be respectively used to operate at different work stations, which also increases the costs of equipment and personnel, and is not conducive to improving production efficiency.

### SUMMARY

In view of at least one defect in the conventional technology described above, an object of the present disclosure is to provide a new type of optocoupler lead frame to improve the CTR consistency of the manufactured opposed optocoupler, reduce manufacturing costs and improve production efficiency.

The technical solutions adopted by the present disclosure are as follows:

A lead frame for an optocoupler is provided. The lead frame is a metal sheet and includes multiple frame units and multiple mutually parallel connecting strips. Respective frame units are arranged at intervals on each of the connecting strips. Each frame unit includes two adjacent functional parts, and two pins perpendicularly connected to the connecting strip. The two functional parts are both located on one side of the connecting strip and are respectively connected to the two pins. Ends of the two pins are located on the other side of the connecting strip; and the area of each functional part is sufficient to accommodate a chip to be installed and fixed, and the chip is any one of a light-emitting chip and a light-sensing chip.

In an embodiment, in each frame unit, a positioning point is provided at a center of each of the two functional parts, and a line connecting the positioning points of the two functional parts is perpendicular to the connecting strip.

In an embodiment, in each frame unit, the two functional parts are respectively a first functional part and a second functional part. The first functional part is close to the ends of the two pins, and the second functional part is away from the ends of the two pins. The first functional part has an area sufficient to accommodate one light-sensing chip to be installed and fixed, and the second functional part has an area sufficient to accommodate one light-emitting chip to be installed and fixed.

In an embodiment, in each of the frame units, the first functional part is separated from the second functional part by a curved slit, to allow a protrusion to form on an edge of the first functional part, and a notch complementary to the protrusion in shape to form on an edge of the second functional part.

Another aspect according to the present disclosure is to provide an optocoupler, which includes two frame units disposed opposite to each other, a light-emitting chip, a light-sensing chip and an encapsulation structure. The two frame units are each the frame unit in the lead frame described above. The functional parts of the two frame units are opposite to each other, and the light-emitting chip and the light-sensing chip are respectively disposed in the two frame units. The light-emitting chip is installed and fixed in one functional part in the frame unit where the light-emitting chip is located and is connected to the other adjacent functional part by a conductive wire. The light-sensing chip is installed and fixed in one functional part in the frame unit where the light-sensing chip is located and is connected to the other adjacent functional part by a conductive wire. The light-emitting chip and the light-sensing chip are positioned opposite to each other. The encapsulation structure encapsulates the two frame units, the light-emitting chip and the light-sensing chip into one body.

In an embodiment, in each frame unit, a positioning point is provided at a center of each of the two functional parts, and a line connecting the positioning points of the two functional parts is perpendicular to the connecting strip. The positioning points of the functional parts of the two frame units are aligned with each other. A fixing position point of the light-emitting chip is aligned with the positioning point of the functional part where the light-emitting chip is located. A fixing position point of the light-sensing chip is aligned with the positioning point of the functional part where the light-sensing chip is located. The light-emitting chip and the light-sensing chip are in a through-beam configuration.

In an embodiment, in each of the frame units, the two functional parts are respectively a first functional part and a second functional part. The first functional part is close to the ends of the two pins, and the second functional part is away from the ends of the two pins. The light-emitting chip is fixed in the second functional part of the frame unit where it is located, and the light-sensing chip is fixed in the first functional part of the frame unit where it is located.

In an embodiment, the encapsulation structure includes an outer encapsulation layer at an outermost side and an inner encapsulation layer wrapping the light-emitting chip, and the material of the inner encapsulation layer is a light-transmitting silicon glue containing a colored pigment.

In an embodiment, the outer encapsulation layer includes a first outer encapsulation layer and a second outer encapsulation layer from inside to outside. The first outer encapsulation layer is made of a light-transmitting white epoxy resin, and the second outer encapsulation layer is made of a light-shielding black epoxy resin.

In an embodiment, the pins of the two frame units both protrude out of the encapsulation structure and are bent toward the same side outside the encapsulation structure.

Another aspect according to the present disclosure is to provide a method for manufacturing an optocoupler, which includes a lead frame manufacturing step, a die bond step, a wire bonding step, a glue dispensing step, a stacking step, an encapsulating step, a dicing and pin bending step. The lead frame is the preceding lead frame. In the die bond step, two pieces of lead frames are taken, in one functional part of each frame unit of one piece of lead frame, one light-emitting chip is installed and fixed, and in one functional part of each frame unit of the other piece of lead frame, one light-sensing chip is installed and fixed. In the wire bonding step, a conductive wire is used to connect the light-emitting chip or the light-sensing chip in each frame unit to the other adjacent functional part. In the stacking step, the two pieces of lead frames are stacked to allow the light-emitting chip and the light-sensing chip on the two pieces of lead frames to be opposite to each other.

In an embodiment, in each of the frame units of the lead frame, a positioning point is provided at a center of each of the two functional parts, and a line connecting the positioning points of the two functional parts is perpendicular to the connecting strip. In the die bond step, the two pieces of lead frames are both placed horizontally, and are respectively in two mutually horizontally flipped states, and in fixing the light-emitting chip, the fixing position point of the light-emitting chip is aligned with the positioning point of the corresponding functional part, and in fixing the light-sensing chip, the fixing position point of the light-sensing chip is aligned with the positioning point of the corresponding functional part.

In an embodiment, in each frame unit of the lead frame, the two functional parts are respectively a first functional part and a second functional part. The first functional part is close to the ends of the two pins, and the second functional part is away from the ends of the two pins; in the die bond step, in the second functional part of each frame unit of one piece of lead frame, a light-emitting chip is fixed, and in the first functional part of each frame unit of the other piece of lead frame, a light-sensing chip is fixed.

In an embodiment, in the die bond step, one die bonder is used, one piece of lead frame is horizontally placed, a conductive glue is dispensed at the positioning point in the second functional part of each frame unit, and then the light-emitting chip is placed; the same die bonder is used, the other piece of lead frame is horizontally placed, a conductive glue is dispensed at the positioning point in the first functional part of each frame unit, and then the light-sensing chip is placed.

In the die bond step, a point alignment correction function of a camera of the die bonder is used, and according to the positioning points in the two functional parts of each frame unit, a machine operation arm is guided to place the light-emitting chip and the light-sensing chip, to allow the fixing position points of the light-emitting chip and the light-sensing chip to be aligned with the positioning points of the corresponding functional parts.

In an embodiment, the wire bonding step includes: a wire bonding machine is used, a piece of lead frame with the light-emitting chip bonded thereto after die bond is placed horizontally, and then a conductive wire is used to electrically connect the light-emitting chip to a bonding point in the functional part adjacent to the light-emitting chip by wiring bonding; the same wire bonding machine is used, the other piece of lead frame with the light-sensing chip bonded thereto after the die bond is placed horizontally, and then a conductive wire is used to electrically connect the light-sensing chip to a bonding point in the functional part adjacent to the light-sensing chip by wiring bonding.

In the wire bonding step, the two pieces of lead frames are respectively in two mutually horizontally flipped states, and the wiring directions for the light-emitting chip and the light-sensing chip are the same.

The optocoupler, its lead frame and its manufacturing method according to the present disclosure have at least the following beneficial effects.
(1) Each frame unit of the lead frame is designed to include two functional parts that can accommodate chips to be installed, so that this kind of lead frame can be used to fix both light-emitting chips and light-sensing chips.
(2) Since the light-emitting chip and the light-sensing chip can use the lead frames having the same structure, the deviation between the opposed positions of the light-emitting chip and the light-sensing chip is reduced. Further, there is no need to develop molds separately to manufacture respective lead frames for the two types of chips, thereby avoiding doubling of the mold developing costs and shortening the period for frame verification, material inspection, and significantly saving the manufacturing costs.
(3) Through the specific arrangement of the two functional parts in each frame unit of the lead frame, in the operation process of die bond for the two types of chips, the same machine can be used to operate at the same work station, and in the operation process of wire bonding for the two types of chips, also the same machine can be used to operate at the same work station, which reduces the investment costs for the equipment and machine inspection personnel, saves the adjustment and turnaround time caused by operations at different work stations, and facilitates improvement of production efficiency.
(4) In manufacturing optocoupler products, two positioning points in each frame unit are used for positioning to achieve double precise positioning of the positioning for the light-emitting chip and the light-sensing chip in the process of die bond, ensuring that in the final product, the light-emitting chip is precisely aligned with the light-sensing chip, thereby ensuring the deviation accuracy of the horizontally opposed positions of the two chips, ensuring the consistency and the proportion of falling into the target range of the product parameters (such as CTR), which is beneficial to improving product yield and product competitiveness. For better understanding and implementation, the present disclosure is described in detail hereinafter with reference to the drawings.

### BRIEF DESCRIPTION OF DRAWINGS

FIG. 1 is a top view of a lead frame of an optocoupler according to the present disclosure, in which a left part in the figure is an enlarged view of a frame unit.

FIG. 2 is a side view of the lead frame of FIG. 1.

FIG. 3 is a front view of the lead frame of FIG. 1.

FIG. 4 is a schematic diagram of a lead frame according to the present disclosure with a light-emitting chip fixed and a wire bonded thereon, in which a left part in the figure is an enlarged view of a frame unit.

FIG. 5 is a schematic diagram of a lead frame according to the present disclosure with a light-sensing chip fixed and a wire bonded thereon, in which a left part in the figure is an enlarged view of a frame unit.

FIG. 6 is a schematic view showing two pieces of lead frames after die bond in a stacked state.

FIG. 7 is a schematic structural view of an optocoupler according to the present disclosure.

FIG. 8 is a view showing an internal structure of the optocoupler of FIG. 7.

FIG. 9 shows the relationship between the test values of product CTR and the center position deviation values of the light-emitting chip and the light-sensing chip.

### REFERENCE LIST

1 lead frame
10 frame unit
101 first functional part
102 second functional part
100 positioning point
S slit
11 pin
110 end of the pin
12 connecting strip
13 frame bar
130 positioning hole
2 optocoupler
21 light-emitting chip
22 light-sensing chip
23 encapsulation structure
230 inner encapsulation layer
24 conductive wire

### DETAILED DESCRIPTION

### First Embodiment

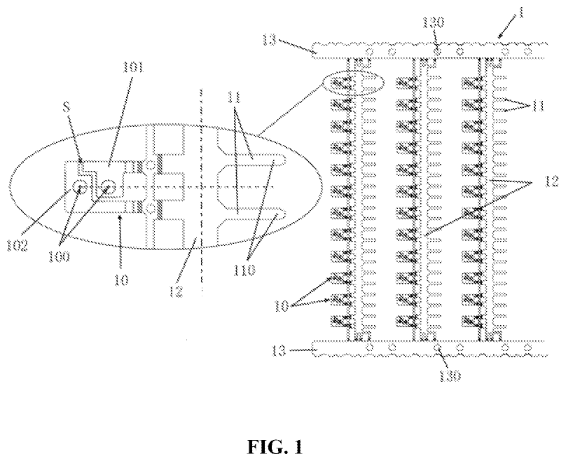

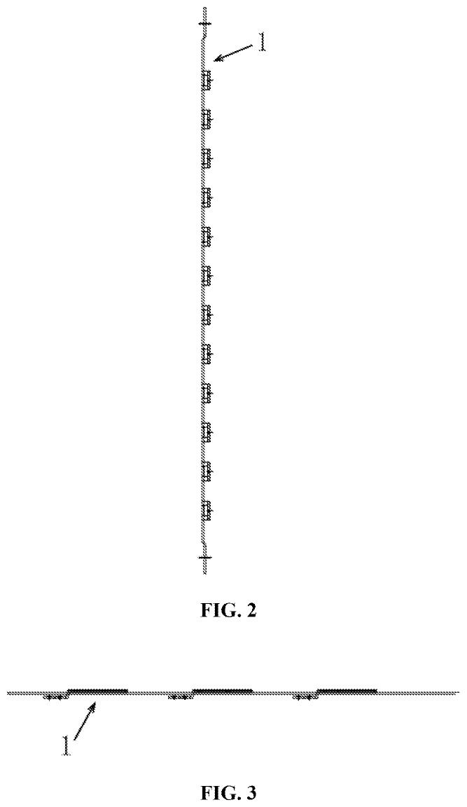

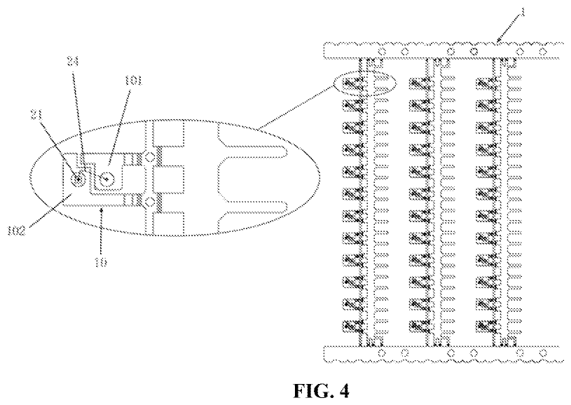

Referring to FIG. 1 to FIG. 3, a lead frame 1 for an optocoupler is provided according to this embodiment. The lead frame 1 is a metal sheet and includes multiple frame units 10 and multiple mutually parallel connecting strips 12. In order to facilitate clear showing of the structure, only part of the lead frame 1 containing three connecting strips 12 are shown in the drawings according to the present disclosure, and practically, the number of connecting strips 12 and frame units 10 is greater than that shown in the drawings and may also be less than that shown in the drawings.

Frame units 10 are arranged at intervals on each connecting strip 12. Each frame unit 10 includes two adjacent functional parts 101, 102 and two pins 11. The two pins 11 are perpendicularly connected to the connecting strip 12. The two functional parts 101 and 102 are both located on one side of the connecting strip 12 and are respectively connected to the two pins 11. Ends 110 of the two pins 11 are located on the other side of the connecting strip 12; and the area of each functional part is sufficient to accommodate a chip to be installed and fixed, and the chip is any one of a light-emitting chip 21 and a light-sensing chip 22.

In an embodiment, in each frame unit 10, a positioning point 100 is provided at a center of each of the two functional parts 101 and 102, and a line connecting the positioning points 100 of the two functional parts 101 and 102 is perpendicular to the connecting strip 12. As shown in FIG. 1, the line connecting the two positioning points 100 is perpendicular to a midline of the connecting strip 12.

Specifically, in each frame unit 10, a center mark and a range mark may be provided in a central part of each of the two functional parts 101 and 102. The center mark is used to form the positioning point 100, and the range mark is used to define a preset chip mounting range or a preset wire bonding range. More specifically, the center mark may be a score in the shape of a symbol “+” engraved on both sides of the functional part, then the positioning point 100 is the center point of the score of the symbol “+”; and the range mark may be a score in the shape of a symbol “O” or “□” engraved on both sides of the functional part, and the range mark surrounds the positioning point of the functional part where the range mark is located.

The two functional parts 101 and 102 are respectively a first functional part 101 and a second functional part 102. The first functional part 101 is close to the ends 110 of the two pins 11, and the second functional part 102 is away from the ends 110 of the two pins 11. The first functional part 101 has an area sufficient to accommodate one light-sensing chip 22 to be installed and fixed, and the second functional part 102 has an area sufficient to accommodate one light-emitting chip 21 to be installed and fixed.

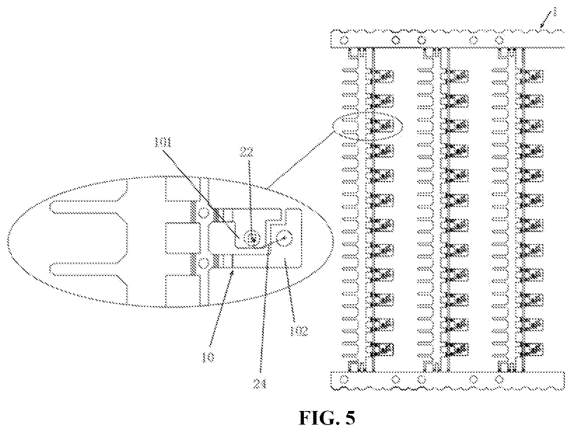

Therefore, in the subsequent process of manufacturing the optocoupler, the same die bonder can be used to perform die bond for the two types of chips at the same work station: a light-emitting chip 21 is placed onto a second functional part 102 of a frame unit 10 in one piece of lead frame 1 using an operating arm, as shown in FIG. 4; and another piece of lead frame 1 is taken and is flipped horizontally, a light-sensing chip 22 is placed onto a first functional part 101 of a frame unit 10 in the another piece of lead frame 1, as shown FIG. 5. Comparing FIG. 4 with FIG. 5, it can be seen that respective lead frames used in the die bond of the two types of chips are placed in two mutually horizontally flipped states or are placed in two states in which the lead frames are mutually rotated by 180° around the parallel axis of the connecting strip 12 and are in the same space positions. In die bond, the two types of chips are placed in the functional parts on the same side of their respective frame units. For example, in the specific examples shown in FIG. 4 and FIG. 5, in die bond, the two types of chips are both placed in the functional parts located at the left side of their respective frame units.

Similarly, in wire bonding, the same wire bonding equipment can be used to perform wire bonding of the two types of chips at the same work station in the same wiring direction. As shown in FIG. 4, when the light-emitting chip 21 of the second functional part 102 is wired, the bonding point of a conductive wire 24 is at the first functional part 101. As shown in FIG. 5, when the light-sensing chip 22 of the first functional part 101 is wired, the bonding point of the conductive wire 24 is at the second functional part 102. Since the respective lead frames in the wire bonding of the two types of chips are also in two mutually horizontally flipped states, the wring directions for the two types of chips are the same. For example, in the specific examples shown in FIG. 4 and FIG. 5, the wring directions for the two types of chips are both from left to right, that is, from the functional part on the left to the functional part on the right.

In order to more conveniently identify the two functional parts or to leave a place for arranging a Zener diode chip, the first functional part 101 is separated from the second functional part 102 by a curved slit S, to allow a protrusion to form on an edge of the first functional part 101 and a notch complementary to the protrusion in shape to form on an edge of the second functional part 102. That is, the shapes of the two functional parts are different. The position of the protrusion of the second functional part 101 may be used to place a Zener diode chip when necessary to improve the anti-static and anti-interference capabilities of the input terminal or the output terminal of the device.

The lead frame 1 further includes two frame bars 13 parallel to each other, playing the role of support and connection. The two frame bars 13 are connected perpendicularly to two ends of the multiple connecting strips 12 respectively, and the multiple connecting strips 12 are arranged at intervals between the two frame bars 13.

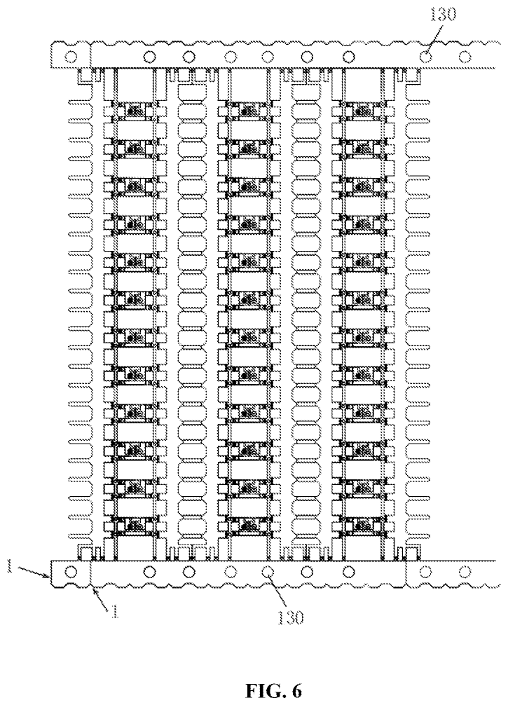

Each frame bar 13 is provided with multiple through positioning holes 130. Therefore, in the subsequent process of manufacturing the optocoupler, two pieces of lead frames 1 with the light-emitting chips 21 and the light-sensing chips 22 fixed thereon respectively may be positioned facing each other by means of the positioning holes 130, facilitating the stacking, as shown in FIG. 6.

Multiple frame units 10 are arranged on the connecting strips 12 at equal intervals.

The connecting strips 12 are arranged between the frame bars 13 at equal intervals, and the interval is just sufficient to accommodate the stacking arrangement of the functional parts of the two frame units 10 facing each other, as shown in FIG. 6.

The material of the lead frame 1 may be one of aluminum alloy, iron-nickel alloy or copper alloy. The thickness of the lead frame 1 ranges from 0.2 mm to 0.3 mm.

In order to improve the reflectivity of the light-emitting chip 21, a highly reflective metal plating layer is provided on at least the surface of each functional part. In an embodiment, the material of the highly reflective metal plating layer is gold or silver.

### Second Embodiment

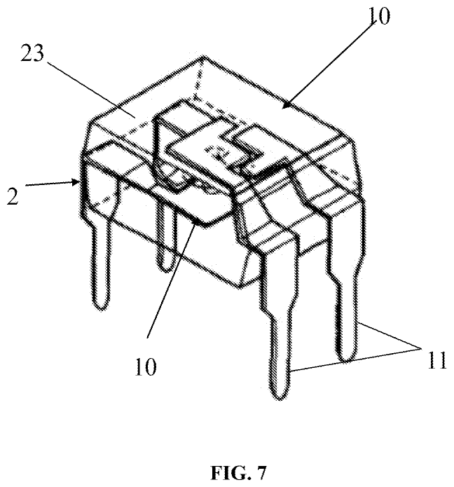

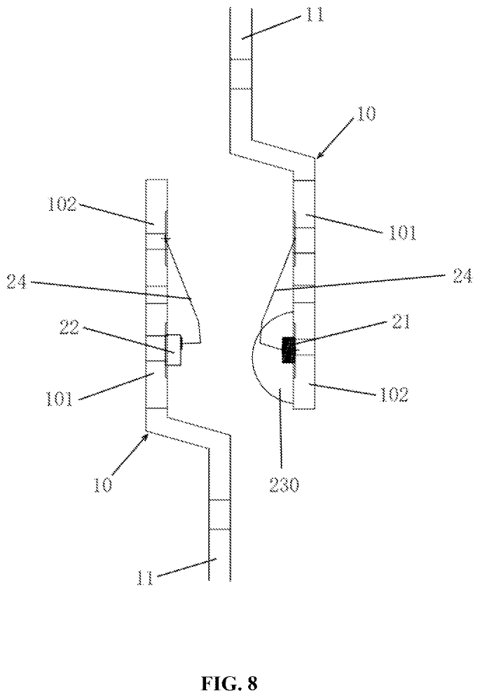

In combination with FIGS. 1 to 8, an optocoupler 2 made from the lead frame 1 according to the first embodiment is provided according to this embodiment. The optocoupler 2 includes two above frame units 10 oppositely disposed from each other, a light-emitting chip 21, a light-sensing chip 22 and an encapsulation structure 23.

The functional parts of the two frame units 10 oppose each other, and the light-emitting chip 21 and the light-sensing chip 22 are respectively disposed in the two frame units 10. The light-emitting chip 21 is installed and fixed in one functional part in the frame unit 10 where the light-emitting chip 21 is located and is connected to the other adjacent functional part by a conductive wire 24. The light-sensing chip 22 is installed and fixed in one functional part in the frame unit 10 where the light-sensing chip 22 is located and is connected to the other adjacent functional part by a conductive wire 24. The light-emitting chip 21 and the light-sensing chip 22 are positioned opposite to each other. The encapsulation structure 23 encapsulates the two frame units 10, the light-emitting chip 21 and the light-sensing chip 22 into one body.

Specifically, the positioning points 100 of the functional parts of the two frame units 10 are aligned with each other; the fixing position point of the light-emitting chip 21 is aligned with the positioning point 100 of the functional part where the light-emitting chip 21 is located; and the fixing position point of the light-sensing chip 22 is aligned with the positioning point 100 of the functional part where the light-sensing chip 22 is located.

More specifically, the first functional part 101 of one frame unit and the second functional part 102 of another frame unit 10 are disposed opposite to each other, and the corresponding positioning points 100 are aligned with each other.

In an embodiment, the light-emitting chip 21 is fixed in the second functional part 102 of the frame unit 10 where the light-emitting chip 21 is located, and the light-sensing chip 22 is fixed in the first functional part 101 of the frame unit 10 where the light-sensing chip 22 is located; and the light-emitting chip 21 and the light-sensing chip 22 are in a through-beam configuration.

The light-emitting chip 21 and the light-sensing chip 22 are specifically fixed to the surfaces of the respective functional parts through conductive glue. The conductive glue may be a conductive paste such as silver glue.

The conductive wire 24 may be a copper wire, an alloy wire or a gold wire.

The encapsulation structure 23 includes an outer encapsulation layer at the outermost side and an inner encapsulation layer 230 wrapping the light-emitting chip 21.

The material of the inner encapsulation layer 230 is a light-transmitting silicon glue containing a colored pigment (such as a red pigment). The main function of doping the colored pigment is to, in a case where the silicon glue is dispensed, allow an apparatus to inspect through an automatic optical inspection (AOI) the inner encapsulation layer 230 coated with the dispensed red silicon glue for example, to determine whether the silicone gel is missed to be dispensed/or whether the shape of the chip or the gel dispensed meets the requirements.

The outer encapsulation layer includes a first outer encapsulation layer and a second outer encapsulation layer from the inside to the outside. The first outer encapsulation layer is made of a light-transmitting white epoxy resin, and the second outer encapsulation layer is made of a light-shielding black epoxy resin.

The pins 11 of both the two frame units 10 protrude out of the encapsulation structure 23 and are bent toward the same side outside the encapsulation structure 23.

In an embodiment, a surface of a part of each of the pins 11 protruding outside the encapsulation structure 23 is plated with a tin layer.

The light-emitting chip 21 is a light-emitting diode, and the light-sensing chip 22 is a photosensitive semiconductor tube. The light-emitting chip 21 may be an infrared light-emitting chip, and the light-sensing chip 22 may correspondingly be an infrared light-receiving chip.

### Third Embodiment

A manufacturing method for the optocoupler 2 according to the second embodiment is provided according to this embodiment, which is roughly the same as the manufacturing method for the conventional optocoupler, and mainly includes steps such as lead frame manufacturing, a die bond, wire bonding, glue dispensing, stacking, encapsulating, pin bending and dicing. The characteristics of the manufacturing method lie in that the lead frame 1 according to the first embodiment is adopted as the lead frame. The manufacturing method is specifically carried out as follows.

In a first step of die bond, two pieces of lead frames 1 are taken, and in one functional part of each frame unit 10 of one piece of lead frame 1, one light-emitting chip 21 is installed and fixed, and in one functional part of each frame unit 10 of the other piece of lead frame 1, one light-sensing chip 22 is installed and fixed.

In this step, the two pieces of lead frames 1 are both placed horizontally and are in two mutually horizontally flipped states. As shown in FIG. 4 and FIG. 5, in fixing the light-emitting chip 21, the fixing position point of the light-emitting chip 21 is aligned with the positioning point 100 in the corresponding functional part, and in fixing the light-sensing chip 22, the fixing position point of the light-sensing chip 22 is aligned with the positioning point 100 in the corresponding functional part. In an embodiment, in the second functional part 102 of each frame unit 10 of one piece of lead frame 1, one light-emitting chip 21 is fixed, and in the first functional part 101 of each frame unit 10 of the other piece of lead frame 1, one light-sensing chip 22 is fixed.

More specifically, in this step, one die bonder is used, one piece of lead frame 1 is horizontally placed, and at the positioning point 100 in the second functional part 102 of each frame unit 10, a conductive glue is dispensed and then a light-emitting chip 21 is placed; and the same die bonder is used, the other piece of lead frame 1 is horizontally placed, and at the positioning point 100 in the first functional part 101 of each frame unit 10, a conductive glue is dispensed and then the light-sensing chip 22 is placed.

Specifically, a point alignment correction function of a camera of the die bonder is used, where the camera is specifically a CCD camera. According to the positioning points 100 in two functional parts of each frame unit 10, a machine operation arm is guided to place the light-emitting chip 21 and the light-sensing chip 22, to allow the fixing position points of the light-emitting chip 21 and the light-sensing chip 22 to be aligned with the positioning points 100 of the corresponding functional parts.

In order to improve accuracy, this step further includes an initial inspection and a sampling inspection. In the initial inspection, after die bond of the frame units 10 is performed on several connecting strips 12 (for example, two connecting strips 12) in the lead frame 1, the lead frame 1 is taken and the position value of the chip is measured under a high-power microscope with a measurement function. The deviation between the fixing position point of the chip and the positioning point 100 in the corresponding functional part is determined according to the position value. If the deviation meets preset requirements, the formal die bond operation will be carried out. If the deviation does not meet the preset requirements, the die bonder is adjusted or repaired. In the sampling inspection, during the formal die bond operation, after a fixed interval of operating time or number of operations, a certain proportion of lead frames 1 are selected to repeat the measurement and determination operations in the initial inspection.

In the initial inspection and sampling inspection, the range mark formed by the score in the shape of the symbol “O” or “□” (the score “O” as shown in FIG. 1, FIG. 4 and FIG. 5) is used to quantitatively measure the position value of the chip. The measured position value of the chip is the value of distance between the edge or center of the chip and the score “O” or “□” in the frame unit.

The quantitative measurement error inspection carried out in the initial inspection and sampling inspection ensures the accuracy of deviation between the opposed horizontal positions of the light-emitting chip and the light-sensing chip, ultimately ensures the consistency and the rate of falling into a target range of the product parameters and improves product competitiveness.

In a second step of high-temperature baking and curing, a constant-temperature curing oven is used to cure the conductive adhesive so that the chip is bonded to the lead frame 1.

In a third step of wire bonding, a conductive wire 24 is used to connect the light-emitting chip 21 or the light-sensing chip 22 in each frame unit 10 to the other functional part adjacent thereto.

Specifically, in this step, as shown in FIG. 4 and FIG. 5, a high-precision wire bonding machine is used, a piece of lead frame 1 with the light-emitting chip 21 bonded thereto after die bond is placed horizontally, and then a conductive wire 24 is used to electrically connect the light-emitting chip 21 to the bonding point in the first functional part 101 adjacent to the light-emitting chip 21 by wiring bonding; the same wire bonding machine is used, the other piece of lead frame 1 with the light-sensing chip 22 bonded thereto after die bond is placed horizontally, and then a conductive wire 24 is used to electrically connect the light-sensing chip 22 to the bonding point in the second functional part 102 adjacent to the light-sensing chip 22 by wiring bonding.

Specifically, the two pieces of lead frames 1 are respectively in two mutually horizontally flipped states, and the wiring directions for the light-emitting chip 21 and the light-sensing chip 22 are the same and are specifically from the left to the right as shown in FIG. 4 and FIG. 5; and the bonding points of the functional parts may be coincident with the positioning points 100 of the functional parts, respectively.

In order to ensure the quality of the wire bonding, this step further includes initial inspection and sampling inspection. In the initial inspection, after wire bonding is performed for the frame units 10 on several connecting strips 12 (for example, two connecting strips 12) in the lead frame 1, the lead frame 1 is taken, and a bonding force of the bonding ball and a force value for the conductive wire fixed point to be torn off are measured on a push-pull machine with a measuring function to determine the quality of the wire bonding. If the quality of the wire bonding meets the preset requirements, the formal wire bonding operation will be carried out. If the quality of the wire bonding does not meet the preset requirements, then the wire bonding machine will be adjusted or repaired. In the sampling inspection, during the formal wire bonding operation, after a fixed interval of operating time or number of operations, a certain proportion of lead frames 1 are selected repeat the measurement and determination operations in the initial inspection.

In a fourth step of glue dispensing, glue is dispensed on the light-emitting chip 21 to form the inner encapsulation layer 230 that encapsulates the light-emitting chip 21.

Specifically, in this step, a high-precision glue dispensing apparatus is used to dispense in a syringe air pressure extrusion manner, a light-transmitting silicone glue with a colored pigment (such as a red pigment) to the region of the light-emitting chip 21, to completely encapsulate the light-emitting chip 21 for protection. The light-transmitting silicone glue can reduce the stress on the light-emitting chip 21 and the bonded wire on the one hand, and on the other hand, enable the heat of the light-emitting chip 21 to be dispersed to improve the conversion efficiency of the light-emitting chip 21, in addition to facilitating visual inspection of the glue amount and the encapsulating position in the glue dispensing.

In a fifth step of high-temperature baking and curing, a programmable constant-temperature curing oven is used to cure the translucent silicone to achieve good shape and stress buffering effects.

In a sixth step of stacking, as shown in FIG. 6, the two pieces of lead frames 1 are stacked together so that the light-emitting chip 21 and the light-sensing chip 22 on the lead frames 1 are in opposed positions.

In this step, specifically, a high-precision automatic chip arrangement machine is used to accurately align the center of the light-emitting chip 21 with the center of the light-sensing chip 22 vertically, to allow the light-emitting chip 21 and the light-sensing chip 22 to form a precise through-beam configuration.

In a seventh step of white glue encapsulating, each pair of frame units 10 disposed opposite to each other is encapsulated with a white epoxy resin to form the first outer encapsulation layer.

In this step, a high-precision encapsulating and molding machine is used to squeeze and fill the white epoxy resin glue, and the internal structure is shaped through high-temperature curing and molding. The white epoxy resin has light-transmitting, pressure resisting and insulating properties, and has silicon oxide (SiO₂) and/or titanium dioxide (TiO₂) appropriately added therein, to further improve the insulation. The silicon dioxide and/or titanium dioxide account for about 15% to 30% of the total weight, which can ensure that the light-transmitting white epoxy resin glue has an appropriate light transmittance and has a thermal expansion coefficient close to that of the black epoxy resin used in a subsequent step.

In an eighth step of residual glue removing, a high-precision punching mold is used to remove unnecessary glue flow channels and flow limiting frames.

In a ninth step of black glue encapsulating, a light-shielding black epoxy resin is wrapped around the aforementioned light-transmitting white epoxy resin to form the second outer encapsulation layer.

In this step, a high-precision encapsulating molding machine is used to squeeze and fill the black epoxy resin glue, and the external structure is shaped through high-temperature curing molding. The black epoxy resin has light-shielding, pressure resisting and insulating properties and serves as the basic reflection for the appearance of the product.

In a tenth step of high-temperature baking and curing, a constant temperature curing oven is used to thoroughly cure the two kinds of epoxy resins encapsulating in the previous steps, to obtain an encapsulation structure 23 in which each pair of frame units 10 disposed opposite to each other, the light-emitting chip 21 and the light-sensing chip 22 are encapsulated integrally.

In an eleventh step of residual glue removing, a high-precision punching mold is used to remove unnecessary glue flowing channels and flow limiting frames.

In a twelfth step of tin plating operation, a surfaces of a part of each of the pins 11 protruding outside the encapsulation structure 23 is plated with a tin layer for protection.

In this step, stannous sulfate and high-purity tin metal blocks are used to allow the tin layer to be uniformly and stably bonded to the surfaces of the metal pins through electrolytic replacement reaction.

In a thirteenth step of dicing and pin bending, a high-precision bending and shaping mold is used to remove single optocouplers 2 from the lead frames, and then bend and shape the metal pins.

In a fourteenth step of performance test, the obtained single products are tested 100% and are sorted.

In the case where the light-emitting chips and the light-sensing chips with the same parameter range are used and other encapsulating materials are kept completely consistent, the lead frame according to the present disclosure and other conventional lead frames are used respectively, to obtain, through the manufacturing method according to the present disclosure and other conventional methods, the optocoupler product in a vertically opposed encapsulating form and other optocouplers in conventional different encapsulating forms for comparison. Specifically, 1000 pcs are taken to perform comparisons of the concentration ratio (for example, average CTR±10%), the proportion of falling into a target range (CTR: 200%-400%), and the average CTR of the product CTR. The comparison results are as follows:

| | | Proportion | |
|---|---|---|---|
| | Concentra- | of falling | |
| | tion | into the | Average |
| Encapsulation form | ratio | range | CTR |
| Horizontal reflective type | 32% | 31% | 220 |
| Obliquely opposed type | 55% | 72% | 280 |
| Conventional vertically | 88% | 93% | 325 |
| opposed type | | | |
| Vertically opposed type in | 98% | 100% | 330 |
| the present disclosure | | | |

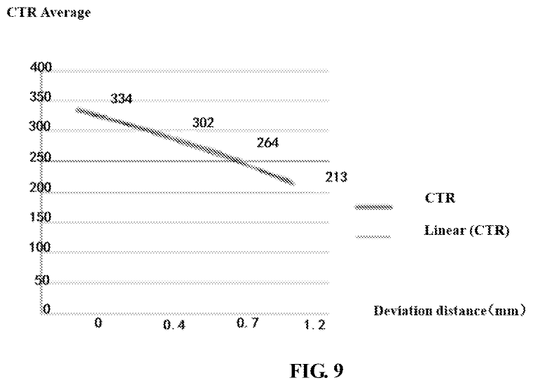

Moreover, as shown in FIG. 9, the smaller the deviation distance, the larger the average CTR value, indicating that the vertically opposed type optocoupler according to the present disclosure has an improved CTR consistency and a reduced deviation.

In the description according to the present disclosure, it is to be noted that for orientation words, such as the terms “center”, “length”, “width”, “thickness”, “upper”, “lower”, “front”, and “back” , “left”, “right”, “vertical”, “horizontal”, “top”, “bottom”, “inside”, “outside” for indicating orientations and positional relationships are based on the orientations or positional relationships shown in the drawings, is only used to facilitate the description according to the present disclosure and simplify the description, rather than indicating or implying that the device or element referred to must have a specific orientation or be constructed and operated in a specific orientation.

In addition, the terms “first” and “second” if used are for descriptive purposes only and should not be understood as indicating or implying relative importance or implicitly indicating the quantity of technical features. Therefore, features defined as “first” and “second” may explicitly or implicitly include one or more of these features. In the description according to the present disclosure, “several” means two or more, unless otherwise clearly and specifically stated.

It should be noted that, for those of ordinary skill in the art, several modifications and improvements can be made without departing from the concept according to the present disclosure, and these modifications and improvements all fall into the protection scope according to the present disclosure.

What is claimed is:

1. A lead frame for an optocoupler, being a metal sheet, and comprising a plurality of frame units and a plurality of mutually parallel connecting strips, wherein respective frame units are arranged at intervals on each of the connecting strips; each of the respective frame units comprises two adjacent functional parts, and two pins perpendicularly connected to the each of the connecting strips, the two functional parts are both located on one side of the each of connecting strips and are respectively connected to the two pins, ends of the two pins are located on another side of the each of connecting strips; and each of the two functional parts has an area sufficient to accommodate a chip to be installed and fixed, and the chip is any one of a light-emitting chip and a light-sensing chip.

2. The lead frame according to claim 1, wherein in the each of the respective frame units, a positioning point is provided at a center of each of the two functional parts, and a line connecting positioning points of the two functional parts is perpendicular to the each of connecting strips.

3. The lead frame according to claim 2, wherein in the each of the respective frame units, the two functional parts are respectively a first functional part and a second functional part, the first functional part is close to the ends of the two pins, and the second functional part is away from the ends of the two pins; and the first functional part has an area sufficient to accommodate one light-sensing chip to be installed and fixed, and the second functional part has an area sufficient to accommodate one light-emitting chip to be installed and fixed.

4. The lead frame according to claim 3, wherein in the each of the respective frame units, the first functional part is separated from the second functional part by a curved slit, to allow a protrusion to form on an edge of the first functional part and a notch complementary to the protrusion in shape to form on an edge of the second functional part.

5. An optocoupler, comprising two frame units disposed opposite to each other, a light-emitting chip, a light-sensing chip and an encapsulation structure, the two frame units are each a frame unit in the lead frame according to claim 1, wherein functional parts of the two frame units are opposite to each other, and the light-emitting chip and the light-sensing chip are respectively disposed in the two frame units; the light-emitting chip is installed and fixed in one functional part in one of the two frame units where the light-emitting chip is located, and is connected to the other adjacent functional part in the one of the two frame units by a conductive wire, the light-sensing chip is installed and fixed in one functional part in the other one of the two frame units where the light-sensing chip is located, and is connected to the other adjacent functional part in the other one of the two frame units by a conductive wire; the light-emitting chip and the light-sensing chip are positioned opposite to each other; and the encapsulation structure encapsulates the two frame units, the light-emitting chip and the light-sensing chip into one body.

6. The optocoupler according to claim 5, wherein in each of the two frame units, a positioning point is provided at a center of each of the two functional parts, and a line connecting the positioning points of the two functional parts is perpendicular to the connecting strip; positioning points of the functional parts of the two frame units are aligned with each other; a fixing position point of the light-emitting chip is aligned with a positioning point of the one functional part where the light-emitting chip is located; a fixing position point of the light-sensing chip is aligned with a positioning point of the one functional part where the light-sensing chip is located; and the light-emitting chip and the light-sensing chip are in a through-beam configuration.

7. The optocoupler according to claim 6, wherein in each of the two frame units, the two functional parts are respectively a first functional part and a second functional part, the first functional part is close to the ends of the two pins, and the second functional part is away from the ends of the two pins; and the light-emitting chip is fixed in the second functional part of the one of the two frame units where the light-emitting chip is located, and the light-sensing chip is fixed in the first functional part of the other one of the two frame units where the light-sensing chip is located.

8. The optocoupler according to claim 5, wherein the encapsulation structure comprises an outer encapsulation layer at an outermost side and an inner encapsulation layer wrapping the light-emitting chip, and a material of the inner encapsulation layer is a light-transmitting silicon glue containing a colored pigment.

9. The optocoupler according to claim 8, wherein the outer encapsulation layer comprises a first outer encapsulation layer and a second outer encapsulation layer from inside to outside, the first outer encapsulation layer is made of a light-transmitting white epoxy resin, and the second outer encapsulation layer is made of a light-shielding black epoxy resin.

10. The optocoupler according to claim 6, wherein the encapsulation structure comprises an outer encapsulation layer at an outermost side and an inner encapsulation layer wrapping the light-emitting chip, and a material of the inner encapsulation layer is a light-transmitting silicon glue containing a colored pigment.

11. The optocoupler according to claim 7, wherein the encapsulation structure comprises an outer encapsulation layer at an outermost side and an inner encapsulation layer wrapping the light-emitting chip, and a material of the inner encapsulation layer is a light-transmitting silicon glue containing a colored pigment.

12. The optocoupler according to claim 5, wherein the pins of the two frame units both protrude out of the encapsulation structure and are bent toward the same side outside the encapsulation structure.

13. The optocoupler according to claim 6, wherein the pins of the two frame units both protrude out of the encapsulation structure and are bent toward the same side outside the encapsulation structure.

14. The optocoupler according to claim 7, wherein the pins of the two frame units both protrude out of the encapsulation structure and are bent toward the same side outside the encapsulation structure.

15. An optocoupler manufacturing method, comprising a step of manufacturing a lead frame, a die bond step, a wire bonding step, a glue dispensing step, a stacking step, an encapsulating step, a dicing and pin bending step, wherein the lead frame is the lead frame according to claim 1, the die bond step comprises: taking two pieces of lead frames, and in one functional part of each frame unit of one of the two pieces of lead frames, installing and fixing one light-emitting chip, and in one functional part of each frame unit of the other one of the two pieces of lead frames, installing and fixing one light-sensing chip; and the wire bonding step comprises: using a conductive wire to connect the light-emitting chip or the light-sensing chip in each frame unit to the other adjacent functional part; and the stacking step comprises stacking the two pieces of lead frames to allow the light-emitting chip and the light-sensing chip on the two pieces of lead frames to be opposite to each other.

16. The optocoupler manufacturing method according to claim 15, wherein in each frame unit of each of the two pieces of lead frames, a positioning point is provided at a center of each of the two functional parts, and a line connecting the positioning points of the two functional parts is perpendicular to the connecting strip; in the die bond step, horizontally placing the two pieces of lead frames in two mutually horizontally flipped states, and in fixing the light-emitting chip, aligning a fixing position point of the light-emitting chip with a positioning point of the one functional part of each frame unit of the one of the two pieces of lead frames, and in fixing the light-sensing chip, aligning a fixing position point of the light-sensing chip with a positioning point of the one functional part of each frame unit of the other one of the two pieces of lead frames.

17. The optocoupler manufacturing method according to claim 16, wherein in the each frame unit of each of the two pieces of lead frames, the two functional parts are respectively a first functional part and a second functional part, the first functional part is close to the ends of the two pins, and the second functional part is away from the ends of the two pins; and in the die bond step, fixing the light-emitting chip in the second functional part of each frame unit of the one of the two pieces of lead frames, and fixing the light-sensing chip in the first functional part of each frame unit of the other one of the two pieces of lead frames,.

18. The optocoupler manufacturing method according to claim 17, wherein the die bond step comprises: using one die bonder, horizontally placing the one of the two pieces of lead frames, dispensing conductive glue at the positioning point in the second functional part of each frame unit, and then placing the light-emitting chip; and using the same die bonder, horizontally placing the other one of the two pieces of lead frames, dispensing conductive glue at the positioning point in the first functional part of each frame unit, and then placing the light-sensing chip; and
in the die bond step, using a point alignment correction function of a camera of the die bonder, and according to the positioning points in the two functional parts of each frame unit, guiding a machine operation arm to place the light-emitting chip and the light-sensing chip, to allow the fixing position points of the light-emitting chip and the light-sensing chip to be aligned with the positioning points of the respective functional parts.

19. The optocoupler manufacturing method according to claim 18, wherein the wire bonding step comprises: using a wire bonding machine, horizontally placing the one of the two pieces of lead frames with the light-emitting chip bonded thereto after the die bond step, and then using a conductive wire to electrically connect the light-emitting chip to a bonding point in the functional part adjacent to the light-emitting chip by wiring bonding; and using the same wire bonding machine, horizontally placing the other one of the two pieces of lead frames with the light-sensing chip bonded thereto after the die bond step, and then using a conductive wire to electrically connect the light-sensing chip to a bonding point in the functional part adjacent to the light-sensing chip by wiring bonding; and
in the wire bonding step, the two pieces of lead frames are respectively in two mutually horizontally flipped states, and wiring directions for the light-emitting chip and the light-sensing chip are the same.

20. The optocoupler manufacturing method according to claim 15, wherein in the each of the respective frame units, a positioning point is provided at a center of each of the two functional parts, and a line connecting positioning points of the two functional parts is perpendicular to the each of connecting strips.
